(19) United States
(12) Patent Application Publication
(10) Pub. No.: US 2009/0253079 A1
(43) Pub. Date: Oct. 8, 2009

(54) FORMING REVERSE ILLUMINATION PATTERNS

(76) Inventors: Fenghong Zhang, Sunnyvale, CA (US); Xinyu Zhang, Palo Alto, CA (US)

Correspondence Address: Haynes and Boone, LLP;IP Section, 2323 Victory Avenue, SUITE 700, Dallas, TX, 75219, US

(21) Appl. No.: 12/098,845

(22) Filed: Apr. 7, 2008

(51) Int. Cl. G03F 7/00

(52) U.S. Cl. 430/322

(57) ABSTRACT

In photolithographic exposure, the illumination pattern (120R) formed on a photosensitive surface (106) is a reverse of the pattern (130) on the optical mask (124). The reverse pattern (120R) is obtained using off-axis illumination when the photosensitive surface is at other than the best focus position.

### BACKGROUND OF THE INVENTION

The present invention relates to photolithography, and more particularly to forming reverse patterns in photoresist and other photosensitive surfaces.

In a photolithographic process, photoresist is formed on a wafer surface and is illuminated by light passing through an optical mask having a pattern of clear and opaque features that define the pattern to be created in the photoresist. The photoresist areas exposed to the light are made more soluble (in the case of positive photoresist) or less soluble (for negative photoresist) in a developer solution. The wafer is then placed into the developer to dissolve the soluble portions of the photoresist. The remaining photoresist (the insoluble portions) provides a photoresist mask used in subsequent processing (e.g. etching, deposition, ion implantation, etc.).

It is sometimes desirable to form mutually reverse patterns of photoresist by means of a single optical mask. This can be done by using a positive photoresist for one pattern and a negative photoresist for the reverse pattern.

Other methods are desirable for producing mutually reverse patterns.

### SUMMARY

This section summarizes some features of the invention. Other features may be described in the subsequent sections. The invention is defined by the appended claims, which are incorporated into this section by reference.

The inventors have discovered that with some photolithographic exposure tools, reverse patterns can be formed by reversing the illumination pattern even with the same type of photoresist (i.e. positive or negative). An illumination pattern is a pattern of exposed and unexposed areas of the photoresist. Typically, the illumination pattern reproduces the optical mask's pattern except for possible shrinkage or magnification. The illumination pattern can be reversed using off-axis illumination if the photoresist layer is placed at selected positions with respect to the optics of the exposure tool. By definition, if the photoresist layer is in the “best focus” position, then the illumination pattern on the photoresist will reproduce the optical mask's pattern (except for possible shrinkage or magnification). Such illumination patterns will be called “direct” illumination patterns herein. The inventors have discovered that positions other than “best focus” exist which will cause the illumination pattern to be reverses. Such positions may be farther away from the exposure tool's objective lens than the best focus position.

The invention is not limited to the features and advantages described above except as defined by the appended claims.

### BRIEF DESCRIPTION OF THE DRAWINGS

FIG. 1 is a side of a photolithographic illumination system used according to some embodiments of the present invention.

FIGS. 2, 3 are views clarifying some features of the system of FIG. 1.

### DESCRIPTION OF SOME EMBODIMENTS

The embodiments described in this section illustrate but do not limit the invention. The invention is defined by the appended claims.

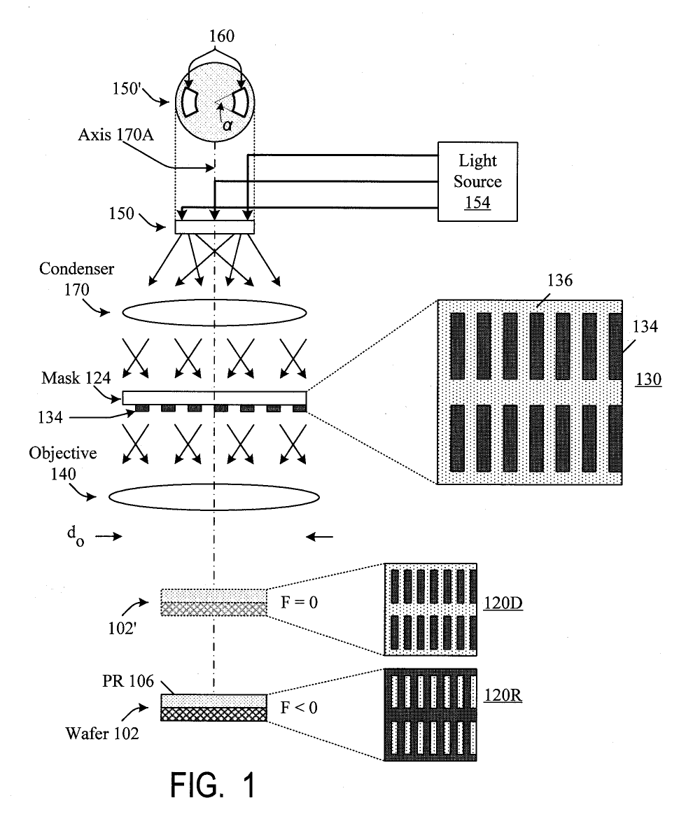

FIG. 1 is a side view of a photolithographic illumination system used to form a photoresist pattern on a wafer 102 covered with a photoresist layer 106. Both direct and reverse illumination patterns can be formed by this system. The direct pattern, shown at 120D in top view, corresponds to a pattern on optical mask 124. The mask pattern is shown in top view at 130. This pattern is an array of lines 134 and spaces 136. The spaces are transparent (clear) to the light used in the system, and the lines are opaque or at least less transparent than the spaces. In the direct pattern 120D, the areas corresponding to the spaces are exposed and the areas corresponding to the lines are not exposed (or at least exposed less so as to create a photoresist pattern when the photoresist is later developed). The direct pattern 120D is thus substantially a copy of the mask pattern 130 except for possible magnification or shrinkage performed by objective lens 140 (shrinkage by a factor of 4 for example).

The reverse illumination pattern, shown at 120R in top view, corresponds to the reverse of the mask pattern. The direct and reverse patterns 120D, 120R may occupy the whole wafer 102 or only a portion of the wafer. In particular, only a portion of the wafer may be exposed by the technique of FIG. 1.

The particular embodiment of FIG. 1 uses Kohler-type illumination with a dipole aperture pattern in the illumination pupil 150. Coherent light from a light source 154 (e.g. a laser) is directed (possibly focused via a collector lens, not shown) onto the pupil 150 having apertures 160 which are two elongated, arcuate diffractive optical elements at the opposite sides of pupil 150. In some embodiments, each aperture 160 is an arc centered at the center of pupil 150 and spanning an angle α of about 40°. (These shapes and dimensions are exemplary and not limiting except as defined by the appended claims.) Each aperture 160 spreads the light in a diffraction-like pattern to illuminate condenser lens 170. The light passing through the two apertures is partially coherent.

Illumination pupil 150 is positioned in the focal plane of condenser lens 170 whose optical axis 170A passes through the center of pupil 150 and hence does not pass through apertures 160 to provide off-axis illumination. Condenser 170 refracts the light emitted from apertures 160 to provide bundles of parallel beams which impinge on optical mask 124. The light transmitted by mask 124 is collected by objective 140, which is large enough to collect the beams of +1 and/or −1 and/or higher diffraction orders. The 0-order beam is not produced in this embodiment.

Objective 140 images the pattern on mask 124 onto the “best focus” plane, shown at F=0, where F is the vertical dimension. If the direct pattern 120D is desired, the wafer should be positioned at the best focus plane (e.g. the best focus plane can be at the top surface or a middle level of resist layer 106). This wafer position is shown at 102′.

The inventors have discovered that the reverse illumination pattern 120R can be obtained by placing the wafer 102 farther away from the objective 140 than the best focus plane. Such positions correspond to F<0.

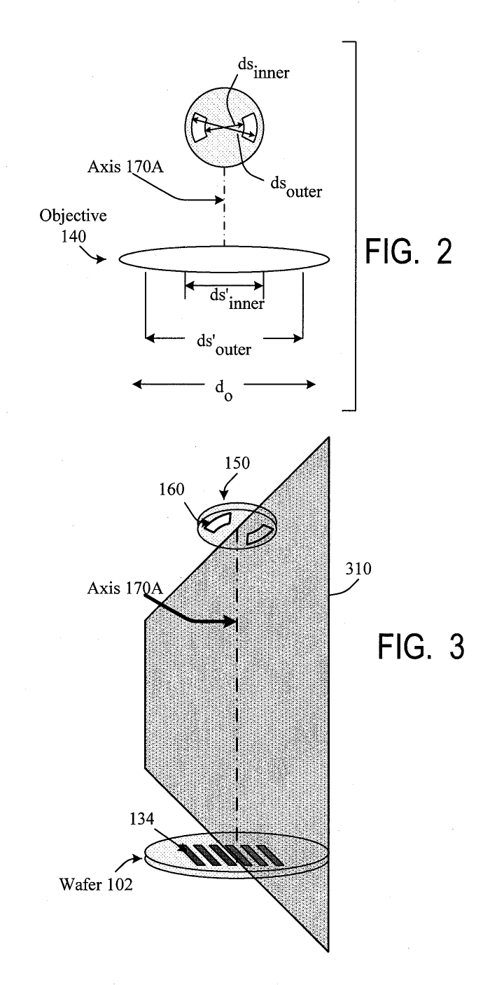

Table 1 below provides suitable values for the F parameter (the distance from the best focus position) observed in some embodiments using the exposure tool of type ASML XT 1250 (Trademark) available from ASML Holding N.V., De Run 6501, 5504 DR Veldhoven, The Netherlands, with the light wavelength λ=193 nm, the wafer diameter of 200 mm, the layer 106 being positive photoresist and being 145 nm thick. The array of lines 134 may have the total length/width dimension of 50 μm/120 nm. The parameters σₒᵤₜₑᵣ and σᵢₙₙₑᵣ in Table 1 are the partial coherence factors corresponding respectively to the outer diameter dsₒᵤₜₑᵣ (FIG. 2) and the inner diameter dsᵢₙₙₑᵣ of apertures 160. The diameter values dsₒᵤₜₑᵣ, dsᵢₙₙₑᵣ correspond respectively to the effective source sizes ds′ₒᵤₜₑᵣ, ds′ᵢₙₙₑᵣ at the position of objective 140, so

σₒᵤₜₑᵣ=ds′ₒᵤₜₑᵣ/dₒ

σᵢₙₙₑᵣ=ds′ᵢₙₙₑᵣ/dₒ

where dₒ is the full objective aperture size.

The DOF (depth of focus) values in Table 1 indicate the range of F values in which the line width obtained after developing the resist 106 is within 10% of the target value. Thus, a table entry of the form F/DOF indicates that the F values must be in the range from F−DOF/2 to F+DOF/2.

TABLE 1
F/DOF (micrometers)

| | Line width/Space width between the lines (nanometers) | | | |
|---|---|---|---|---|
| σₒᵤₜₑᵣ/σᵢₙₙₑᵣ | 95/95 | 120/120 | 140/140 | 350/360 |
| 0.95/0.75 | −0.25/0.05 | −0.25/0.25 | −0.25/0.25 | −0.4/0.2 |
| 0.95/0.65 | None | −0.3/0.2 | −0.3/0.2 | −0.4/0.15 |
| 0.95/0.57 | None | None | −0.3/0.15 | −0.45/0.1 |

If the line/space width is 500/500 nm, a good reverse illumination pattern is not believed to be achievable with the σₒᵤₜₑᵣ/σᵢₙₙₑᵣ parameters listed in Table 1.

The invention is not limited to the embodiments described above, and in particular to a specific exposure tool, wavelength, or photoresist type or thickness. The invention includes forming the reverse pattern 120R regardless of whether or not the same mask 124 is used to form the direct pattern 120D. The lines 134 may form a one-dimensional or two-dimensional arrays. In some embodiments, at least 10 lines 134 are provided in each row of the array (the “row” is the direction in which the long sides of lines 134 are adjacent to each other; this is the horizontal dimension in the patterns 130, 120D, 120R in FIG. 1). The invention is not limited to any partial coherence values.

Some embodiments include a method for forming an illumination pattern on a photosensitive surface of a structure. The structure can be wafer 102 which may or may not include semiconductor materials (e.g. silicon). The photosensitive surface can be the top surface of photoresist 106 or some other photosensitive layer, e.g. polyimide. The photosensitive layer may or may not remain in final structure. The final structure may be an integrated circuit for example.

In some embodiments, the illumination pattern on the photosensitive surface is reverse to a pattern on an optical mask. This means that the reverse pattern is obtained by reversing the optical mask's pattern with or without shrinkage or magnification. The illumination pattern is formed by light emitted by one or more effective light sources. The effective light sources may or may not be real light sources. These may be apertures 160 as in FIGS. 1, 2. Alternatively, only one aperture 160 can be provided, or any number of apertures. The apertures can be elongated as in FIGS. 1, 2, or can be pinholes. The elongated apertures can extend generally in parallel to the lines.

The optical mask is placed between a condenser lens and an objective lens. The condenser and objective lenses can each be a lens system including multiple lenses. In some embodiments, the condenser's optical axis lies in a plane that does not intersect the one or more effective light sources. For example, in FIG. 3, the condenser's optical axis 170A lies in a vertical plane 310 which does not intersect the effective light sources 160. The lines 134 on the optical mask are parallel to plane 310.

In some embodiments (see e.g. Table 1), the lines and spaces each have a width (e.g. 95 nm to 360 nm) which is at least 40% and at most 200% of a light wavelength (e.g. 193 nm) provided by the one or more effective light sources.

Other embodiments and variations are within the scope of the invention, as defined by the appended claims.

1. A method for forming an illumination pattern on a photosensitive surface of a structure, the illumination pattern being reverse to a pattern on an optical mask, the illumination pattern being formed by light emitted by one or more effective light sources, the photosensitive surface being sensitive to said light, the method comprising:
placing the optical mask between a condenser lens and an objective lens, the condenser lens concentrating said light from the one or more effective light sources onto said optical mask; and
causing an objective lens to transmit, onto the photosensitive surface, the light concentrated by the condenser and transmitted by the optical mask;
wherein the condenser's optical axis lies in a plane that does not intersect said one or more effective light sources;
wherein the pattern on the optical mask is an array of lines with spaces between the lines, the spaces being clear with respect to said light emitted by the one or more effective light sources, wherein the lines are more opaque with respect to the light emitted by the one or more effective light sources than the spaces;
wherein the lines are parallel to said plane.

2. The method of claim 1 wherein the structure is positioned farther away from the objective lens than a best focus position.

3. The method of claim 1 wherein the one or more effective light sources comprise at least one effective light source on each side of said plane.

4. The method of claim 1 wherein the lines and spaces each have a width which is at least 40% and at most 200% of a light wavelength provided by the one or more effective light sources, the photosensitive surface being sensitive to said wavelength.

5. The method of claim 1 wherein:
said one or more effective light sources provide a light wavelength of 190˜200 nm to which the photosensitive surface is sensitive;
the one or more effective light sources comprise an effective light source with an outer partial coherence value of 0.95 and an inner partial coherence value of 0.57 to 0.75; and
a line/space width of the lines and spaces is 95 nm/95 nm to 350 nm/360 nm.

6. The method of claim 1 wherein:
said one or more effective light sources provide a light wavelength of 193 nm to which the photosensitive surface is sensitive;
the one or more effective light sources comprise an effective light source with an outer partial coherence value of 0.95 and an inner partial coherence value of 0.75, 0.65, or 0.57; and
a line/space width of the lines and spaces is 95 nm/95 nm or 120 nm/120 nm or 140 nm/140 nm or 350 nm/360 nm.

7. The method of claim 5 wherein the structure is positioned farther away from the objective lens than a best focus position, and the distance between the structure position and the best focus position is 0.20˜0.45 micrometers.

8. The method of claim 1 further comprising developing the photosensitive surface to obtain a pattern of photosensitive material in said structure.

9. The method of claim 8 wherein said structure comprises a semiconductor substrate.

10. The method of claim 1 wherein the one or more effective light sources are in the condenser lens' focal plane.

11. The method of claim 1 wherein the reverse pattern shrunk relative to the pattern on the optical mask.

12. A method for forming an illumination pattern on a photosensitive surface of a structure, the illumination pattern being reverse to a pattern on an optical mask, the illumination pattern being formed by light emitted by one or more effective light sources, the photosensitive surface being sensitive to said light, the method comprising:
placing the optical mask between a condenser lens and an objective lens, the condenser lens concentrating said light from the one or more effective light sources onto said optical mask; and
causing an objective lens to transmit, onto the photosensitive surface, the light concentrated by the condenser and transmitted by the optical mask;
wherein the pattern on the optical mask is an array of lines with spaces between the lines, the spaces being clear with respect to said light emitted by the one or more effective light sources, wherein the lines are more opaque with respect to the light emitted by the one or more effective light sources than the spaces;
wherein the one or more light sources provide off-axis illumination of the photosensitive surface, and at least one of the light sources is elongated in a general direction along said lines.
